(19) United States
(12) Patent Application Publication
(10) Pub. No.: US 2007/0123046 A1
(43) Pub. Date: May 31, 2007

(54) Continuous in-line monitoring and qualification of polishing rates

(75) Inventors: Abraham Ravid, Cupertino, CA (US); Doyle E. Bennett, Santa Clara, CA (US); Konstantin Y. Smekalin, Pleasanton, CA (US)

Correspondence Address: FISH & RICHARDSON P.C., P.O. BOX 1022, MINNEAPOLIS, MN, 55440-1022, US

(73) Assignee: Applied Materials, Inc.

(21) Appl. No.: 11/590,655

(22) Filed: Oct. 30, 2006

Related U.S. Application Data
(60) Provisional application No. 60/732,263, filed on Oct. 31, 2005.

(51) Int. Cl. H01L 21/66; H01L 21/76; H01L 21/461

(52) U.S. Cl. 438/692; 438/401; 438/14

(57) ABSTRACT

A CMP tool can be closed loop controlled by using data, for a first polished wafer, obtained by an in-line metrology station, an in-situ monitoring system, and/or an inter-platen monitoring system to continually monitor and qualify polishing rates for the processing of subsequent polished wafers.

### CROSS-REFERENCE TO RELATED APPLICATIONS

This application claims the benefit of priority of U.S. Provisional Application Ser. No. 60/732,263, filed on Oct. 31, 2005, which is incorporated by reference herein.

### BACKGROUND

The present invention relates generally to chemical mechanical polishing (“CMP”) of substrates, and more particularly to controlling a CMP process.

An integrated circuit is typically formed on a substrate by the sequential deposition of conductive, semiconductive, or insulative layers on a silicon wafer. One fabrication step involves depositing a filler layer over a non-planar surface, and planarizing the filler layer until the non-planar surface is exposed. A conductive filler layer, for example, can be deposited on a patterned insulative layer to fill the trenches or holes in the insulative layer. The conductive filler layer and insulative layer can be, for example, a copper layer and a dielectric layer, respectively. The filler layer is then planarized until the raised pattern, i.e., a top surface, of the insulative layer is exposed. After planarization, the portions of the conductive layer remaining between the raised pattern of the insulative layer form metal features, for example, vias, plugs and lines that provide conductive paths between thin film circuits on the substrate.

CMP is one suitable method of planarization. In general, a CMP tool mounts a wafer at a polishing station and polishes a surface of the wafer by moving the wafer across and/or around a polishing pad. A polishing slurry is typically used in conjunction with the pad. The slurry contains at least one chemically-reactive agent and can include abrasive particles. The CMP tool can house multiple polishing stations. Each polishing station can employ distinct polishing parameters, conditions, and techniques. By way of example, a polishing station can employ a particular polishing slurry, a particular polishing pad (having a particular type of surface), a recipe of particular applied pressures, a particular polishing time, and particular one or more metrology devices. With some CMP tools, the first polishing station polishes down the conductive filler layer, which, as discussed above, can be a copper layer. One or more subsequent polishing stations then polish away a barrier material, if present, and any copper that is not part of the copper features of an integrated circuit. Underpolishing the wafer leaves copper and barrier material on the top surface of the insulative layer (i.e., the dielectric layer) of the wafer and leads to current leakage. Overpolishing wears away too much of the copper features increasing resistance and nonuniform conductivity of the integrated circuits. One cause of over or underpolishing is a change in polishing rate at a polishing station caused by, for example, wear of the polishing pad and/or other consumables.

FIG. 1 shows an example of a silicon wafer 11. The wafer 11 can include one or more dies, for example, die 21. Typically, the wafer 11 includes approximately 400 dies. Each die usually includes multiple integrated circuits. The integrated circuits located within each die include copper features 31 that are isolated from one another by dielectric material 61. The region within the die 21 where the copper features 31 are dense provides an array 41, whereas regions of the die that are free of copper features 31 provide fields 51. In the instant specification, a thickness of the dielectric layer in the field is referred to as the field dielectric thickness, and a thickness of the dielectric layer in the array is referred to as an array dielectric thickness.

A wafer can and usually does include dies having different metal-to-dielectric surface area coverage ratios. A metal-to-dielectric surface area coverage ratio of a die is the ratio of (i) the surface area of the die that is covered by metal and (ii) the surface area of the die that is covered by dielectric. By way of example, the metal-to-dielectric surface area ratios of a first type of die and a second type of die on the wafer can be 1:9 and 9:1, respectively. The surface area of the first type of die is covered with 10% metal and 90% dielectric material, and the surface area of the second type of die is covered with 90% metal and 10% dielectric material. In the instant specification, metal-to-dielectric surface area coverage ratios are indicated as n×m, where n indicates the metal contribution and m indicates the dielectric contribution. FIG. 2A shows a test wafer 202 which includes three types of dies, a 1×9 die 204, a 9×1 die 206, and a 1×1 die 208. FIG. 2B shown an exploded view of a product wafer that includes a scribe line 212 that, in turn, includes test areas of various metal-to-dielectric ratios, for example, test areas 214, 216, and 218. A test area, like a die, can include one or more metal features and, furthermore, can have an array region and a field region.

### SUMMARY

The present invention provides methods and apparatus, including computer-program products, for continuous in-line monitoring of polishing rates. Monitoring is effected based on data obtained and/or calculated from any combination of in-situ and in-line monitoring devices. The data includes at least (i) a ratio of a field dielectric thickness and an array dielectric thickness (i.e., D/A) for a die having a first metal-to-dielectric surface area coverage ratio and (ii) D/A for a die having a second metal-to-dielectric surface area coverage ratio that is different than the first metal-to-dielectric surface area coverage ratio.

In one implementation, a first wafer is subject to the polishing steps of a CMP process and one or more properties of the first wafer are measured. Measurement can be effected at an in-line metrology station, an in-situ monitoring module, and/or an inter-platen monitoring module. Data is obtained and/or calculated, including the above described ratios of field dielectric thickness to array dielectric thickness. The data is then input into a calculus to determine the following: (i) when an overall polishing rate of the CMP process has changed; (ii) which polishing step or steps of the CMP process caused the change; (iii) whether the polishing step or steps determined to caused the change in the overall polishing rate should be disqualified; and (iv) new polishing parameters for the polishing step or steps disqualified. The parameters are sent to the CMP tool and used to supplement or replace the previous polishing parameters. Subsequent wafers of the batch are polished on the CMP tool using the revised polishing parameters. Examples of polishing parameters include and are not limited to polishing time, slurry composition, slurry dispensing rate, polishing pad composition, rotational speed of the platen, rotational speed of the carrier head, polishing temperature, and carrier head pressure. The first wafer can be either a test wafer or a product wafer.

In one general aspect, the invention features a computer-program product that is tangibly stored on machine-readable medium. The product includes instructions operable to cause a processor to receive a first ratio. The first ratio is a ratio of field dielectric thickness to array dielectric thickness for a first region of interest of a first wafer that was polished in a polishing process that includes two polishing steps. The first region of interest has a first metal-to-dielectric surface area coverage ratio, and the polishing process has an overall polishing rate. The product includes instructions to receive a second ratio. The second ratio is a ratio of field dielectric thickness to array dielectric thickness for a second region of interest of the first wafer. The second region of interest has a second metal-to-dielectric surface area coverage ratio that is different than the first metal-to-dielectric surface area coverage ratio. The product includes instructions to determine, in response to a detected change in the overall polishing rate and based at least in part on the first and second ratios, which of the first and second polishing step caused the detected change.

In another general aspect, the invention features a computer-implemented method for closed loop control in chemical mechanical polishing using an inline metrology station. The method includes polishing a wafer in a first polishing step. The wafer has, before polishing, a conductive filler layer, a barrier layer, and a patterned dielectric layer. The conductive filler layer overlies the barrier layer, and the barrier layer overlies the patterned dielectric layer. The first polishing step is configured to remove a portion of the conductive filler layer to expose a top surface of the barrier layer. The method includes polishing the wafer in a second polishing step that is configured to remove the barrier layer to expose a top surface of the patterned dielectric layer. The method includes obtaining, for a first region of interest on the wafer, a first ratio of field dielectric thickness to array dielectric thickness. The first region of interest has a first metal-to-dielectric surface area coverage ratio. The method includes obtaining, for a second region of interest on the wafer, a second ratio of field dielectric thickness to array dielectric thickness. The second region of interest has a second metal-to-dielectric surface area coverage ratio that is different from the first metal-to-dielectric surface area coverage ratio. The method includes, when there is a change in an overall polishing rate of the first and second polishing steps, determining which of the first and second polishing steps caused the change. The determining is based, at least in part, on the first ratio of field dielectric thickness to array dielectric thickness and second ratio of field dielectric thickness to array dielectric thickness.

In another general aspect, the invention features a system for chemical mechanical polishing. The system includes a first polishing station configured to effectuate a first polishing step of a polishing process. The first polishing step is configured to remove a metal layer of a wafer to expose a top surface of an underlying barrier layer of the wafer. The system includes a second polishing station configured to effectuate a second polishing step of the polishing process. The second polishing step is configured to remove the barrier layer to expose a top surface of an underlying dielectric layer of the wafer. The system includes a metrology station configured to obtain, after a wafer is polished at the first and second polishing stations, a field dielectric thickness and an array dielectric thickness of two or more dies on the wafer. A first of the two or more dies having a first metal-to-dielectric surface area coverage ratio, and a second of the two or more dies having a second metal to dielectric surface area coverage ratio that is different than the first metal to dielectric surface area coverage ratio. The system includes a controller configured to calculate ratios of field dielectric thickness and array dielectric thickness for at least the first and second of the two or more dies. The controller is further configured to determine, in response to a detected change in an overall polishing rate, which of the first and second polishing stations caused the change, wherein the determination is based, at least in part, on the calculated ratios.

The invention can be implemented to realize one or more of the following advantages. A system in accordance with the invention can automatically and continuously qualify polisher performance based on polishing rates. As will be discussed below, qualification generally refers to a process in which there is a determination that polishing rate or rates have not changed to the point where they will cause under or over polishing that exceeds polishing process limits such that a change in the polishing process is required. Given a CMP process that includes at least two polishing steps performed at different polishing stations, each polishing step polishing at a particular polishing rate, the system can detect changes in the polishing rates from wafer to wafer and, furthermore, determine which of the polishing steps has changed. (The polishing rates in the two polishing steps are typically different but, alternatively, can be substantially the same.) The system can continuously monitor the polishing rate, make the described determination, and change polishing parameter as required to improve the uniformity of polishing rates from wafer to wafer.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 illustrates the various different regions of a wafer.

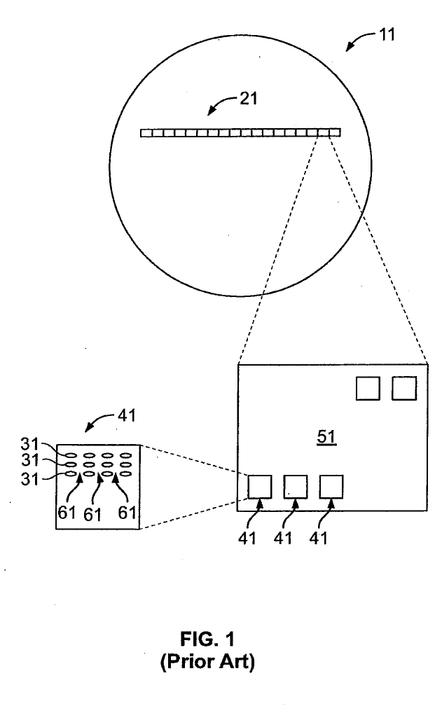

FIG. 2A illustrates an example of a wafer with multiple dies.

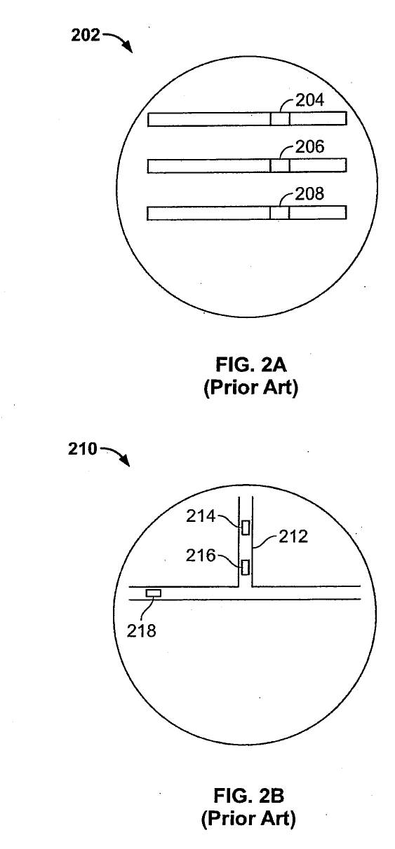

FIG. 2B is an exploded view of a scribe line between adjacent dies.

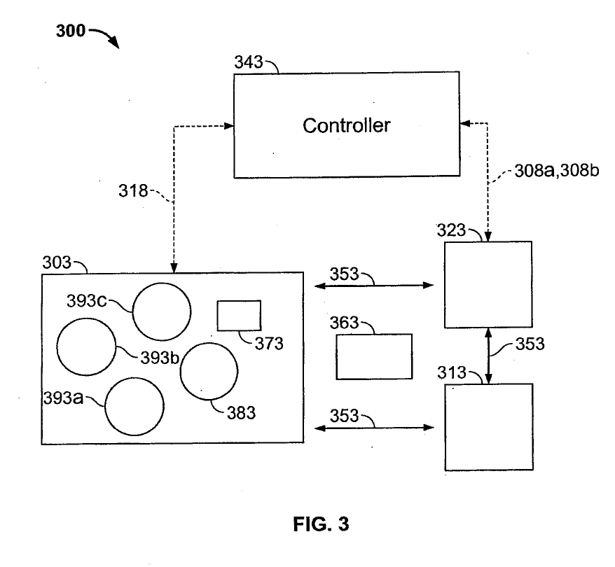

FIG. 3 shows a chemical mechanical polishing system.

FIGS. 4A-4E illustrate a CMP process for removing a conductive layer and/or a barrier layer to clear a top surface of a dielectric layer of a wafer.

FIG. 5 shows a method 500 for continuous in-line monitoring and qualification of the CMP process that includes a set up stage and a continuous polishing stage.

FIG. 6 shows an implementation of the continuous polishing stage.

Like reference symbols in the various drawings indicate like elements.

### DETAILED DESCRIPTION

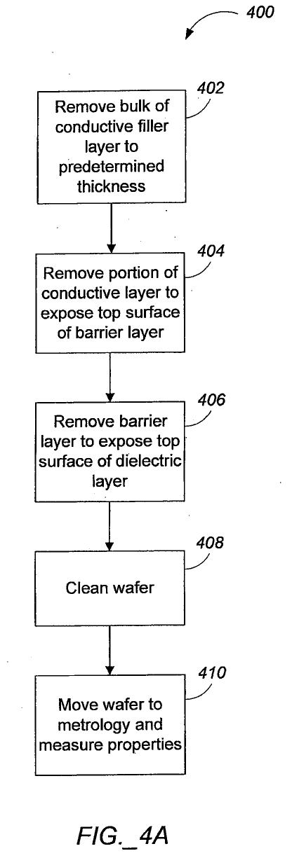

FIG. 3 shows a CMP system 300 suitable for performing the polishing steps described in the instant specification. The CMP system 300 includes a CMP tool 303, a cassette storage unit 313, a metrology station 323, a robot 363, and a controller 343. The CMP system 300 can include other units, exist in a configuration different than the one depicted, or include different (fewer or additional) components that perform the same tasks as the components described. For example, the CMP tool 303 can include one or more inter-platen monitoring modules, each of which being configured to use, for example, white light to effect measurements of one or more properties of a wafer being transported from one platen to another. A suitable inter-platen monitoring module is described in commonly owned U.S. patent application Ser. No. 11/187,612, filed on Jul. 22, 2005, which is hereby incorporated by reference.

In operation, the robot 363 transfers wafers 353 to and from the cassette storage unit 313, the CMP tool 303, and the metrology station 323. The CMP tool 303 houses a transfer station 383 and three polishing stations 393a, 393b, 393c (platen 1, platen 2, and platen 3). Typically, each polishing station includes a rotatable platen bearing a polishing pad. Although the CMP tool 303 depicted houses three polishing stations 393a, 393b, 393c, the CMP tool can have a different number of polishing stations. Optionally, the CMP system 300 can include a cleaner 373 for cleaning wafers.

Each polishing station can include one or more in-situ monitoring modules that are operable to measure film thickness or changes in film thickness during polishing. The in-situ monitoring modules can include one or more eddy current sensors, one or more non-eddy current sensors, or various combinations of eddy current and non-eddy current sensors. Examples of non-eddy current sensors include but are not limited to optical sensors, friction sensors, and torque sensors. In-situ eddy current monitoring modules are described in commonly owned U.S. Publication No. 2005-0024047 A1, which is hereby incorporated by reference.

There are numerous methods of moving wafers through the CMP system 300. One possible method is for the robot 363 to take an unpolished wafer 353 from cassette storage 313 and transfer it to the transfer station 383 in the CMP tool 303. The transfer station 383 facilitates the movement of the wafer 353 from one polishing station to the another, typically, by loading the wafer into a carrier head that is movable between the transfer station and the platens. Each polishing station can have different parameters and conditions for polishing the wafer 353. The polishing parameters can include, but are not limited to, polishing time, slurry composition, slurry dispensing rate, polishing pad composition, rotational speed of the platen, rotational speed of the carrier head, polishing temperature, and carrier head pressure. After the wafer 353 has been polished on each of the polishing stations 393a, 393b, 393c it can be moved to the cleaner 373 where the wafer 353 is cleaned. The cleaner 373 can also be a separate apparatus from the CMP tool 303. A description of a similar system for polishing and cleaning wafers can be found in U.S. Pat. No. 6,413,145, the entire disclosure of which is incorporated herein by reference.

The robot 363 then can transfer the wafer 353 to and from the metrology station 323. The metrology station 323 has the ability to measure one or more properties of polishing, for example, dishing, erosion, metal film thickness, barrier thickness, and dielectric thickness. The metrology station 323 can measure these properties at multiple locations on the wafer surface, including locations in an array and locations in a field of a die. The measurements can be stored or output to another station in the CMP system 300. The metrology station 323 can be an integrated metrology system that includes different metrology devices. An example of two suitable metrology stations 323 are the NovaScan 2020 for 200 mm wafers and the NovaScan 3030 for 300 mm wafers, both available from Nova Measuring Devices, Ltd., of Rehovot, Israel.

The measurements taken by the metrology station 323, the in-situ monitoring modules, and/or an inter-platen monitoring module can be sent to the controller 343. The controller 343 is a programmable computer that uses the measurements to monitor and qualify the CMP process being implemented by the CMP system. The controller can detect a change in polishing rate (due to, for example, wear of consumables) and determine which of the polishing stations has changed its polishing rate, as will be described below. The controller can calculate new polishing parameters to correct changes in the polishing rate. Polishing parameters are described below.

Furthermore, the controller 343 can use the measurements to calculate polishing parameters or recipes for polishing stations 393b and 393c. The controller 343 can communicate the polishing parameters to the CMP tool 303. The controller 343 can perform calculations of the polishing parameters using a data-based model, as described in U.S. patent application Ser. No. 60/396,755, filed Jul. 19, 2002, the entire disclosure of which is incorporated herein by reference. The controller 343 can alternatively or additionally communicate with each of the polishing stations 393b and 393c. The controller 343 can be one device or multiple devices that calculate and communicate with the CMP tool 303 or with each of the polishing stations 393b and 393c. The polishing parameters replace or supplement previous parameters and are used on a subsequent wafer in a batch of wafers that move through the CMP system 300. A batch of wafers may include wafers that have been similarly processed, wafers with the same pattern of features, wafers with the same dielectric material, wafers that have been processed together within a particular time frame, wafers from a same cassette, or another series of wafers that may be grouped together. Often a single batch of wafers includes 25-50 wafers. Wafers that have not been completely polished can be affected by the post-polishing measurements taken from a polished wafer 353. Wafers that have completed their polish can be processed through a corrective recipe based on the metrology data and an amount by which the recipe should be adjusted.

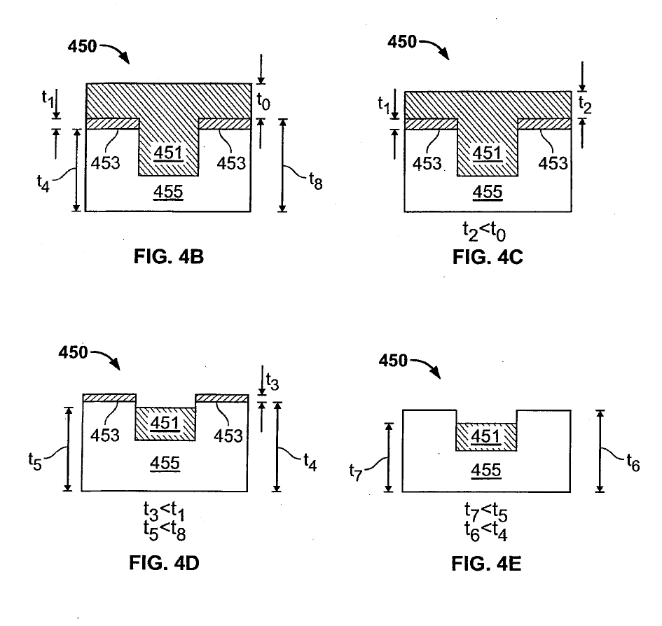

FIGS. 4A-4E illustrate a CMP process 400 for removing a conductive filler layer and/or a barrier layer to clear a top surface of a dielectric layer of a wafer. CMP process 400 can be performed by a CMP system, for example, the above-described CMP system 300.

As shown in FIG. 4B, a wafer 450, before being subject to CMP process 400, includes a conductive filler layer 451, a barrier layer 453, and a dielectric layer 455. The conductive filler layer 451 has a pre-polish thickness t₀. The barrier layer 453 has a pre-polish thickness t₁. The dielectric layer 455 has a pre-polish thickness t₄. The wafer 450 can include additional layers underlying the dielectric layer 455. For ease of exhibition, FIGS. 4B-4E show only a portion of the wafer 450. The portion shown is an array portion and includes a metal feature in a trench of dielectric material.

As shown in FIG. 4A, CMP system 300 removes the bulk of the conductive filler layer 451 to a predetermined thickness t₂ (step 402 of FIG. 4A). The conductive filler layer 451 can be a copper layer. Alternatively, the conductive filler layer can be composed of other conductive material or materials. Step 402 can be performed at polishing station 393a. FIG. 4C shows the result of step 402. The conductive filler layer 451 (after the polishing of step 402) has a thickness t₂ that is less than its pre-polish thickness of t₀. The thickness of the barrier layer 453 is unchanged.

CMP system 300 further polishes the conductive filler layer 451 to remove a portion of the conductive filler layer 451 overlying the barrier layer 453 so that a top surface of the barrier layer 453 is exposed (step 404). Removal can include clearing the conductive filler layer 451 from the top surface of the barrier layer 453 so that no residue of the conductive filler material remains on top of the top surface of the barrier layer 453. Step 404 can be performed at polishing station 393b and typically removes a small portion of the barrier layer 453. As can be seen from FIG. 4D, after it has been subject to the polishing of steps 402 and 404, the barrier layer 453 of the wafer 450 has a thickness t₃ that is less than its pre-polished thickness t₁. Furthermore, some expected dishing has occurred. That is, t₅ is less than t₈. (Dishing is generally the reduction in thickness of the metal feature due to polishing.)

CMP system 300 removes the remaining portion of the barrier layer 453 to expose a top surface of the dielectric layer 455 (step 406). Removing can include clearing the remaining portion of the barrier layer 453 from a top surface of the dielectric layer 455 so that no residue of barrier layer material remains on top of the top surface of the dielectric layer. Step 406 can be implemented at polishing station 393c. As can be seen from FIG. 4E, in performing step 406, CMP system 300 caused erosion of the array dielectric thickness, i.e., t₆ is less than t₄, and exacerbated dishing, i.e., t₇ is less than t₅.

For each of the above described polishing steps, the end point time and overpolish time are calculated from measurements taken by the in-situ monitoring modules located in each polishing station. The end point time is a calculation of when the polishing step is completed. The overpolish time is the period of time that polishing continues after the end point time and is usually determined by an in-situ end-point detection system.

Optionally, CMP system cleans the wafer (step 408). Cleaning can be effected by cleaner 373.

CMP system 300 moves the wafer to a metrology station and measures one or more properties of the wafer (step 410). The measured properties include, for example, dishing, erosion, and dielectric thickness. Other properties can be measured depending on wafer composition existing at this point in processing. The measurements are taken at multiple locations on the wafer surface, including field and arrays regions of dies having different metal-to-dielectric surface area coverage ratios. As an alternative to measuring at a metrology station, the wafer can be measured by devices located inside the process flow (e.g., an in-situ monitoring module and/or an inter-platen monitoring module situated between platens.) Optionally, steps 402 and 404 can be combined into one polishing step and performed at one polishing station so that the above described CMP process includes only two polishing steps. The polishing station performing the combined step can polish at different polishing rates. For example, the polishing station can initially polish at a first rate and, after a predetermined point of polishing has been reached, polish at a second that is less than the first rate.

As indicated above, the polishing rates of the above described polishing steps can change from wafer-to-wafer as consumables, for example, polishing pads, wear from use. These changes, when not accounted for, might lead to under and overpolishing, which are undesirable, as discussed above. Thus, it is usually necessary to monitor these rates and verify that they have not changed to the point where they will cause under or over polishing. In the instant specification, such verification is referred to as qualification.

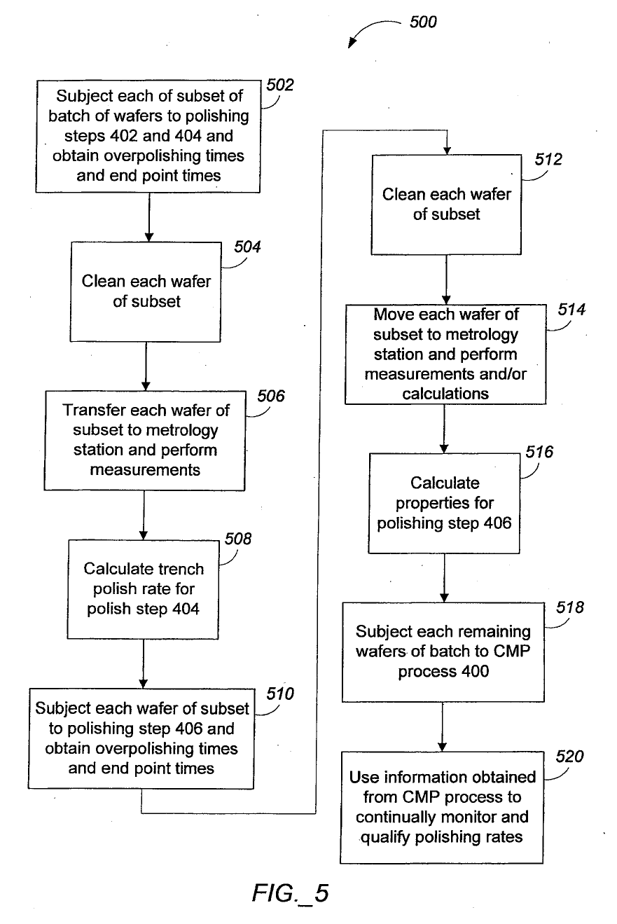

FIG. 5 shows a method 500 for continuous in-line monitoring and qualification of CMP process 400. Method 500 includes an initial set up stage that provides, for the above described polishing steps 404 and 406, the starting polishing rates of metal in trenches, against which subsequent polishing rates can be compared. The initial set up stage includes steps 502-516, which are described below. Method 500 also includes a continuous polishing stage, in which the above described CMP polishing process 400 can be performed, as well as continuously monitored and qualified. The continuous polishing stage includes steps 518 and 520, which are described below.

A subset of a batch of wafers, for example, three to five wafers of the batch, are subject to the above-described polishing steps 402 and 404 and the end point times and overpolish times for each polishing step are recorded (step 502). The end point times and overpolish times are determined from the above-described in-situ monitoring devices. An end point time is generally the actual time when an end point is detected. An overpolish time generally can be calculated as the difference between the end point time and a polish time (the latter of which is a value that is calculated based on an estimated polish rate for a current wafer). In one implementation, nominal polishing parameters are used. As discussed above, polishing steps 402 and 404 are performed at polishing stations 393a and 393b, respectively.

Optionally, each wafer of the subset is cleaned (step 504). Cleaning can be performed at, for example, the cleaner 373 (FIG. 3).

Each wafer of the subset is transferred to an integrated meteorology station and measurements are taken (step 506). The integrated metrology station can be, for example, metrology station 323 (shown in FIG. 3). Instruments of the metrology station are used to measure dishing, erosion, barrier thickness, and dielectric thickness at multiple locations on the surface of each wafer. As indicated above, dishing is generally the reduction in the thickness of a metal feature due to polishing, erosion is the loss of thickness of dielectric material in an array due to polishing, barrier thickness is the thickness of the barrier material, and array dielectric thickness is the thickness of a layer of dielectric material that is in an array and that is situated between metal features. As an alternative to transferring a wafer to the metrology station to effect measurements, measurements can be effected by an inter-platen monitoring module while the wafer is being transported from platen to platen and/or by an in-situ monitoring module while the wafer is being polished.

The measured properties are used to calculate the trench polish rate (for each measurement location on the wafer) for polishing step 404 (step 508). The trench polishing rate for the polishing step 404 indicates the rate at which the polishing step 404 removes metal in the trenches in the dielectric layer. In one implementation, trench polish rate is calculated as dishing (measured at step 506 using instruments at the metrology station) divided by the overpolish time for the polishing step 404 (obtained at step 502). That is,
P2CuRR=Dishing/P2OPT (Eq. 1)
where, P2CuRR is the platen 2 or polishing step 404's copper removal rate, and P2OPT is the platen 2 or polishing step 404's overpolish time. (For the present discussion of method 500, polishing step 404 is performed at platen 2, and references to platen 2 or P2 correspond to references to polishing step 404. Additionally, polishing step 406 is performed at platen 3, and references to platen 3 or P3 correspond to references to polishing step 406.)

At this point, the properties obtained, either by measurement and/or calculation include: trench polish rate for the polishing step 404; dielectric thickness post polishing step 404 but before polishing step 406, i.e., the P3 incoming dielectric thickness measured at the metrology station in step 506; barrier thickness post polishing step 404 but before polishing step 406, i.e., the P3 incoming barrier thickness measured at the metrology station in step 506; and array dielectric thickness post polishing step 404 but before polishing step 406, i.e., P3 incoming array dielectric thickness.

Each wafer of the subset is moved to the CMP tool 303 and subjected to polishing step 406 and end point times and overpolish times are recorded (step 510). As discussed above, polishing step 406 removes the barrier layer from a top surface of the dielectric layer.

Optionally, each wafer of the subset is cleaned (step 512). As discussed above, cleaning can be performed at, for example, the cleaner 373 (FIG. 3).

Each wafer of the subset is moved to the metrology station, and dishing, erosion, and dielectric thickness at multiple locations on the surface of each wafers are measured and/or calculated (step 514). The properties measured in the instant step are post P3, i.e., taken after polishing step 406. As an alternative to transferring a wafer to the metrology station to effect measurements, measurements can be effected by an inter-platen monitoring module while the wafer is being transported from platen to platen and/or by an in-situ monitoring module while the wafer is being polished.

Properties for polishing step 406 are calculated (step 516). The properties calculated include: the barrier removal rate, dielectric removal rate, a ratio of the field dielectric thickness and array dielectric thickness (the thicknesses were measured in the previous step), and a copper removal rate.

The barrier removal rate can be calculated as a ratio of (i) the barrier thickness measured after the second polishing step and before the third polishing step, i.e., incoming P3 barrier thickness measured in step 506, and (ii) the end point time for the third polishing step. That is,
P3BRR=P2B/P3EPT (Eq. 2)
where, P3BRR is the platen 3's barrier removal rate, P2B is the post platen 2 barrier thickness, and P3EPT is the platen 3's time to clear away the barrier from open dielectric areas. These parameters can also be obtained or derived from in-situ monitoring systems and/or an inter-platen monitoring module.

The dielectric removal rate can be calculated as a ratio of (i) the incoming P3 dielectric thickness minus the post P3 dielectric thickness (which thicknesses are measured at the metrology station in steps 506 and 514) and (ii) the overpolish time for the third polishing step. That is,
P3DRR=(P2D−P3D)/P3OPT (Eq. 3)
where, P3DRR is the platen 3's dielectric removal rate, P2D is the post platen 2 dielectric thickness, P3D is the post platen 3 dielectric thickness, and P3OPT is the platen 3's overpolish time that is the time after P3EPT was reached.

The ratio of the field dielectric thickness and array dielectric thickness can be calculated as the field dielectric thickness measured in step 514 divided by the array thickness measured in step 514.

The copper removal rate for the third polishing step can be calculated according to the following equation:
P3CuRR={P3Dish−[(P2CuRR·P2PT)+(P3DRR·P3OPT)+(P3BRR·P3EPT)]}/P3PT (Eq. 4)
where, P3CuRR is the platen 3's copper removal rate, P3Dish is the post platen 3 dishing measured at step 514, P2CuRR (as discussed above) is the platen 2's trench removal rate calculated in step 508, P2PT is the platen 2's polish time (which is the sum of the end point time and the overpolish time), P3DRR is the platen 3's dielectric removal rate calculated in the instant step, P3OPT is the platen 3's overpolish time, P3BRR is the platen 3's barrier removal rate as calculated in the instant step, P3EPT is the platen 3's end point time, and P3PT is the platen 3's polish time (which is the sum of the end point time and the overpolish time).

If the end point data is not available, it is possible to approximate, based on slurry calibration information, a combined barrier and dielectric removal rate for the third polishing step. The approximation is effective because the barrier layer thickness is typically constant from wafer to wafer and relatively thin (usually no more than 250 angstroms) in comparison to the amount of dielectric layer(s) removed, which can be as much as ten times the barrier thickness.

At this point, the initial set up stage is complete and the information obtained from the set up stage can be used to monitor and qualify polishing rates in a subsequent continuous polishing stage. Note that the initial set up stage is essentially CMP polishing process 400 with the extra steps taken to measure polishing properties at the in-line metrology station (or other measurement devices) after polishing step 404 and before polishing step 406 (i.e., steps 504-508).

In the continuous polishing stage, each wafer is subject to the following steps. The above-described CMP polishing process 400 is performed on each of the remaining wafers of the batch (step 518). The polishing process includes moving a polished wafer to the metrology station and measuring and/or calculating dishing, erosion, field dielectric thickness, and array dielectric thickness at a few locations, including at dies having different metal-to-dielectric surface area coverage ratios, for example, a 1×9 die, a 9×1 die, and a 1×1 die.

The information obtained in step 518 is used to detect a change of the overall polishing rate, qualify polishing rate(s) from wafer-to-wafer, and/or change polishing parameters from wafer-to-wafer (step 520). Changing polishing parameters can include a determination of which of the polishing stations (or polishing steps) contributed to a change in polishing rate.

The following describes detection of changes in polishing rates and qualification of polishing steps. Changes in any of the measured dishing, erosion, field dielectric thickness, and array dielectric thickness for a current wafer in comparison to a previously polished wafer can indicate a change in the overall polishing steps. In order to qualify polishing rates for which there are indications of change, these thickness changes can also be compared to thresholds of thickness changes to qualify, from wafer-to-wafer, polishing steps. The actual values that constitute a change, a large change, and a non-change (i.e., the values are unchanged) in method 500 depend on the particular polishing process and can be empirically determined. A significant change, for example, in thickness from the previous wafer to a current wafer can indicate that one or more of the polishing rates have changed to the point where they should no longer be qualified. Alternatively or additionally, the polishing rates for the current wafer can be approximately calculated using the information obtained from the initial set up procedure and then compared to polishing rates calculated in the initial set up procedure. Changes in polishing rates inside an acceptable range can be qualified (and changes to one or more polishing parameters are not required), whereas changes that are outside of the acceptable range should be disqualified (and changes to one or more polishing parameters are required).

Polishing rates, i.e., P2CuRR, P3BRR, P3DRR, and P3CuRR, for the current wafer can be approximately calculated as follows. P2CuRR can be approximately calculated by using Eq. 1 and the dishing obtained in the initial set up procedure. The assumption made here is that dishing caused by polishing at the second platen has remained substantially the same over the polishing of a batch of wafers. The P2OPT is provided by the in-situ monitoring device at platen 2 and can be used as an indicator of process stability.

P3BRR can be approximately calculated by using Eq. 2 and the P2B obtained in the initial set up procedure or, alternatively, measured by an inter-platen monitoring module for every wafer traveling between platen 2 and platen 3. The assumption made here is that the P2B remains substantially the same over the polishing of a batch of wafers. The EPT is provided by the in-situ monitoring device at platen 3.

P3DRR can be approximately calculated by using Eq. 3 and the P2D obtained in the initial set up procedure or, alternatively, measured by an inter-platen monitoring module or an in-situ monitoring module for every wafer. The P3D and P3OPT are provided by the metrology measurement made after polishing the current wafer at platen 3 and/or the in-situ monitoring device or a metrology system located at platen 3.

P3CuRR can be approximately calculated by using Eq. 4 and the P2CuRR, P3BRR, and P3DRR approximately calculated for the current wafer. P3Dish is provided by the metrology measurement made after polishing the current wafer at platen 3. P2PT, P3OPT, and P3EPT are provided by the in-situ monitoring devices at platens 2 and 3.

The following describes the changing of polishing parameters. As discussed above, changing parameters can include, in addition to one or more calculations of new polishing parameters, a determination of which of the platens 2 and 3 (i.e., polishing steps 404 and 406) caused a change in the overall polishing rate. The determination is based, at least in part, on the D/A of dies having different metal-to-dielectric surface area coverage ratios, for example, one or more 1×9 dies, one or more 9×1 dies, and one or more 1×1 dies. Without being limited to any particular theory, dies that are on a same wafer but that have different metal-to-dielectric surface area coverage ratios respond differently when polishing rates change. By inspection of the responses of these dies, one can determine which of the platens 2 and 3 caused the overall change in polishing rate. In one implementation, a table of D/A (e.g., Table 1 below) is implemented to facilitate the determination. The table can be stored in non-volatile memory of a controller of the polishing process, for example, the above-discussed controller 343.

TABLE 1

| | | | Polishing Rate that | |
|---|---|---|---|---|
| | | | changed and direction | |
| D/A for 9 × 1 die | D/A for 1 × 9 die | D/A for 1 × 1 die | of change | Comments |
| Decreased | Unchanged or | Increased | P3DRR increased | Can be validated by |
| | increased | (More erosion in P3) | | measuring dielectric |
| | | | | thickness |
| Increased | Unchanged or | Decreased | P3DRR decreased | (P2 process has |
| | decreased | Less erosion in P3) | | not changed) |
| Increased | Decreased | Large increased | P3CuRR increased | P2 Cu effect on |
| | | (Much more | | erosion would |
| | | erosion in P3) | | be minimal |
| Increase | Unchanged | Unchanged or | P2CuRR increased | |
| | | slight increase | | |
| Decreased | Unchanged | Decreased | P2CuRR decreased | |

The D/A for the three dies can be used to determine which of and how the polishing rates have changed. By way of example, if D/A decreased from wafer to wafer for the 9×1 die, remains unchanged from wafer to wafer for the 1×9 die, and decreased from wafer to wafer for the 1×1 die, then P2CuRR has probably decreased. When D/A for more than one of a same die type is obtained, the multiple D/As can be averaged. Obtaining D/A for multiples of a same die type can remove precision errors. The above-described logic can be applied separately for different dies across the wafer, enabling within wafer polish rate control.

As can be seen from the above table, a change in dielectric removal rate on either platen generally affects a die which surface area is mostly dielectric, for example, a 1×9 die, such that the D/A of the die is usually unchanged or not significantly changed.

After a determination of which platen caused the overall change in polishing rate has been made, one or more polishing parameters for the platen identified in the determination can then be adjusted. In one implementation, only polishing time is changed. Alternatively, other or additional polishing parameters can be changed. Changes made are generally based on information available from properties obtained by the in situ monitoring devices and/or metrology station during the polishing and post polishing measuring, respectively, of the current wafer. The polishing model of the platen identified can be used to calculate the change in polishing parameter.

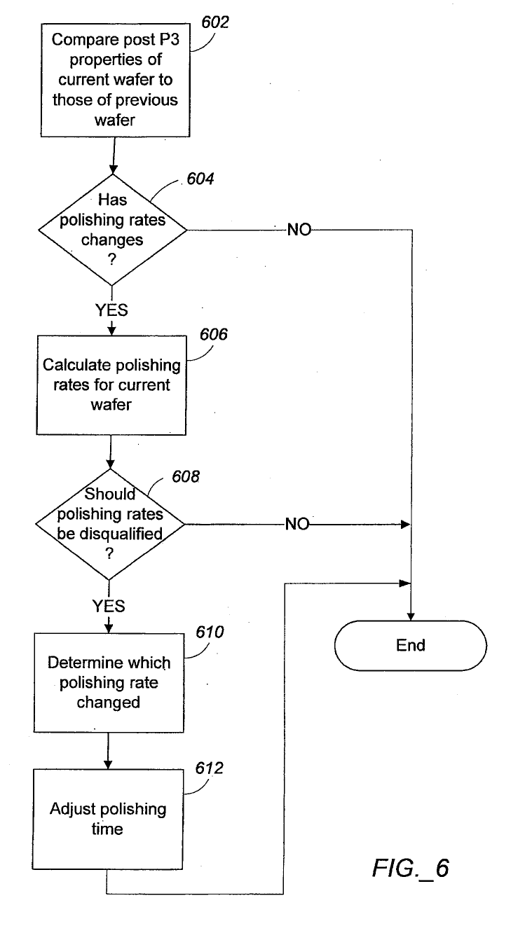

FIG. 6 shows an implementation of step 520. Post P3 dishing, erosion, and dielectric thicknesses (field and array) obtained for a current wafer are compared to the same thickness for the previously polished wafer (step 602). A determination is made as to whether polishing rates have changed (step 604). The determination is based on the results of the comparison of step 602. If no change in polishing rates is determined to have occurred, then the process ends. Otherwise, polishing rates for the current wafer are approximately calculated (step 606). The calculations are performed as described above in reference to step 520 of FIG. 5. A determination is made as to whether the polishing rates should be disqualified (step 608). The determination of disqualification is based, at least in part, on differences between (i) polishing rates approximately calculated for the current wafer, i.e., those calculated in step 606, and (ii) polishing rates calculated in the initial set up procedure (as discussed above in reference to steps 502-516). If polishing rates are not disqualified, then the process ends. Otherwise, a determination is made as to which of the polishing rates (i.e., P2CuRR, P3BRR, P3DRR, P3CuRR) has changed (step 610). The determination is made by using a table of D/As for dies having different metal-to-dielectric surface area coverage ratios as described above in reference to step 520 of FIG. 5. Polishing time is then adjusted to re-qualify the polishing rate identified in the previous step (step 612). The new polishing time is calculated based on the appropriate polishing model, i.e., the model being used for the platen having the changed polishing rate identified in step 610. Additionally, it is possible to provide predictions, for a process about to reach future disqualification conditions, as warnings if attempts to get the polish process back on track fail.

A number of implementations of the invention have been described. Nevertheless, it will be understood that various modifications may be made without departing from the spirit and scope of the invention. For example, although the specification describes a copper damascene polishing process, the invention can be implemented to work with metals and other polishing processes, as long as D/A thicknesses can be measured for dies having different metal-to-dielectric surface area coverage ratios. Moreover, surface area coverage ratios for material other than metal and dielectric can be implemented, as long as the materials being considered respond differently to processing, which can be, for example, a material specific polishing process. The D/A table described above can be empirically and/or theoretically determined for the particular polishing process. The D/A can be calculated from thicknesses within a die, in a test region, or in a region of interest. (A region of interest can be a die on a test wafer, a die on a product wafer, or a test region on a product wafer.) Method steps can be performed in an order that is different than that presented. Accordingly, other embodiments are within the scope of the following claims.

What is claimed is:

1. A computer-implemented method for closed loop control in chemical mechanical polishing using an inline metrology station, comprising:
polishing a wafer in a first polishing step, the wafer having, before polishing, a conductive filler layer, a barrier layer, and a patterned dielectric layer, the conductive filler layer overlying the barrier layer and the barrier layer overlying the patterned dielectric layer, the first polishing step being configured to remove a portion of the conductive filler layer to expose a top surface of the barrier layer;
polishing the wafer in a second polishing step that is configured to remove the barrier layer to expose a top surface of the patterned dielectric layer;
obtaining, for a first region of interest on the wafer, a first ratio of field dielectric thickness to array dielectric thickness, the first region of interest having a first metal-to-dielectric surface area coverage ratio;
obtaining, for a second region of interest on the wafer, a second ratio of field dielectric thickness to array dielectric thickness, the second region of interest having a second metal-to-dielectric surface area coverage ratio that is different from the first metal-to-dielectric surface area coverage ratio; and
when there is a change in an overall polishing rate of the first and second polishing steps, determining which of the first and second polishing steps caused the change, the determining being based, at least in part, on the first ratio of field dielectric thickness to array dielectric thickness and second ratio of field dielectric thickness to array dielectric thickness.

2. The method of claim 1, wherein:
each of the regions of interest is one of a die or a test region.

3. The method of claim 1, wherein the wafer is a current wafer, the method further comprising:
obtaining, for a first region of interest on a previously polished wafer, a third ratio of field dielectric thickness to array dielectric thickness, the previously polished wafer's first region of interest having the first metal-to-dielectric surface area coverage ratio; and
obtaining, for a second region of interest on the previously polished wafer, a fourth ratio of dielectric thickness to array dielectric thickness, the previously polished wafer's second region of interest having the second metal-to-dielectric surface area coverage ratio; wherein
determining which of the first and second polishing steps caused the change in overall polishing rate includes comparing the first and third ratios of field dielectric thickness to array dielectric thickness and comparing the second and fourth ratios of field dielectric thickness to array dielectric thickness.

4. The method of claim 3, further comprising:
obtaining, for a third region of interest of the current wafer, a fifth ratio of dielectric thickness to array dielectric thickness, the current wafer's third region of interest having a third metal-to-dielectric surface area coverage ratio; and
obtaining, for a third region of interest of the previously polished wafer, a sixth ratio of dielectric thickness to array dielectric thickness, the previously polished wafer's third region of interest having the third metal-to-dielectric surface area coverage ratio; wherein
determining which of the first and second polishing steps caused the change in overall polishing rate further includes comparing the fifth and sixth ratios of field dielectric thickness to array dielectric thickness.

5. The method of claim 4, wherein:
the first, second, and third metal-to-dielectric surface area coverage ratios are nine to one, one to nine, and one to one, respectively.

6. The method of claim 4, further comprising:
when the second polishing step is determined to have caused the change in the overall polishing rate, determining which one or more of a metal removal rate of the second polishing step, a barrier removal rate of the second polishing step, or a dielectric removal rate of the second polishing step has changed.

7. The method of claim 6, further comprising:
when the first polishing step is determined to have caused the change in the overall polishing rate, determining whether a metal removal rate of the first polishing step has increased or decreased.

8. The method of claim 7, further comprising:
for a removal rate that is determined to have changed, determining whether the removal rate increased or decreased.

9. The method of claim 8, further comprising:
for a removal rate that is determined to have changed, assessing whether the removal rate is to be qualified.

10. The method of claim 9, wherein:
assessing whether the removal rate is to be qualified includes calculating the removal rate for the current wafer.

11. The method of claim 10, wherein the wafers polished are part of a batch of wafers, the method further comprising:
performing a set up procedure, for two or more wafers of the batch of wafers, to calculate an initial value of the removal rate; wherein
assessing whether the removal rate determined to have changed is to be qualified includes comparing the removal rate calculated for the current wafer with the initial value of the removal rate calculated from performance of the set up procedure.

12. The method of claim 1, wherein:
the first polishing step is implemented on a first polishing station, and the second polishing step being implemented on a second polishing station.

13. The method of claim 1, wherein:
the first polishing step includes a third polishing step and a fourth polishing step, the third polishing step being implemented at a first polishing station, the fourth polishing step being implemented at a second polishing station; and
the second polishing step being implemented at a third polishing station.

14. A computer-program product, tangibly stored on machine-readable medium, the product comprising instructions operable to cause a processor to:
receive a first ratio, the first ratio being a ratio of field dielectric thickness to array dielectric thickness for a first region of interest of a first wafer that was polished in a polishing process that includes two polishing steps, the first region of interest having a first metal-to-dielectric surface area coverage ratio and the polishing process having an overall polishing rate;
receive a second ratio, the second ratio being a ratio of field dielectric thickness to array dielectric thickness for a second region of interest of the first wafer, the second region of interest having a second metal-to-dielectric surface area coverage ratio that is different than the first metal-to-dielectric surface area coverage ratio; and
in response to a detected change in the overall polishing rate, determine, based at least in part on the first and second ratios, which of the first and second polishing steps caused the detected change.

15. The product of claim 14, further comprising instructions to:
receive a third ratio, the third ratio being a ratio of field dielectric thickness to array dielectric thickness for a first region of interest of a second wafer that was polished in the polishing process, the second wafer's first region of interest having the first metal-to-dielectric surface area coverage ratio; and
receive a fourth ratio, the fourth ratio being a ratio of field dielectric thickness to array dielectric thickness for a second region of interest of the second wafer, the second wafer's second region of interest having the second metal-to-dielectric surface area coverage ratio; wherein
instructions to determine includes instructions to compare the first and third ratios and instructions to compare the second and fourth ratios.

16. The product of claim 15, wherein:
instructions to determine includes instructions to determine which of the first and third ratios is greater and which of the second and fourth ratios is greater.

17. The product of claim 15, further comprising instructions to:
receive a fifth ratio, the fifth ratio being a ratio of field dielectric thickness to array dielectric thickness for a third region of interest of the first wafer, the first wafer's third region of interest having a third metal-to-dielectric surface area coverage ratio that is different from the first and second metal-to-dielectric surface area coverage ratios; and
receive a sixth ratio, the sixth ratio being a ratio of field dielectric thickness to array dielectric thickness for a third region of interest of the second wafer, the second wafer's third region of interest having the third metal-to-dielectric surface area coverage ratio; wherein
instructions to determine includes instructions to compare the fifth and sixth ratios.

18. The product of claim 17, wherein:
the first, second, and third metal-to-dielectric surface area coverage ratios are nine to one, one to nine, and one to one, respectively.

19. A system for chemical mechanical polishing, comprising:
a first polishing station configured to effectuate a first polishing step of a polishing process, the first polishing step being configured to remove a metal layer of a wafer to expose a top surface of an underlying barrier layer of the wafer;
a second polishing station configured to effectuate a second polishing step of the polishing process, the second polishing step being configured to remove the barrier layer to expose a top surface of an underlying dielectric layer of the wafer;
a metrology station configured to obtain, after a wafer is polished at the first and second polishing stations, a field dielectric thickness and an array dielectric thickness of two or more dies on the wafer, a first of the two or more dies having a first metal-to-dielectric surface area coverage ratio and a second of the two or more dies having a second metal-to-dielectric surface area coverage ratio that is different than the first metal-to-dielectric surface area coverage ratio; and
a controller configured to calculate ratios of field dielectric thickness and array dielectric thickness for at least the first and second of the two or more dies, the controller being further configured to determine, in response to a detected change in an overall polishing rate, which of the first and second polishing stations caused the change, wherein the determination is based, at least in part, on the calculated ratios.

20. The system of claim 19, wherein:
the controller is further configured to determine, when the second polishing step is determined to have caused the change in the overall polishing rate, which one or more of a metal removal rate of the second polishing step, a barrier removal rate of the second polishing step, or a dielectric removal rate of the second polishing step has changed.
